(19) United States
(12) Patent Application Publication
(10) Pub. No.: US 2020/0098320 A1
(43) Pub. Date: Mar. 26, 2020

(54) IMPEDANCE DIFFERENCE COMPENSATION CIRCUIT, DISPLAY PANEL AND MOBILE TERMINAL

(71) Applicant: HKC CORPORATION LIMITED, Shenzhen, Guangdong (CN)

(72) Inventor: Beizhou Huang, Shenzhen, Guangdong (CN)

(21) Appl. No.: 16/312,332

(22) PCT Filed: Nov. 13, 2018
(86) PCT No.: PCT/CN2018/115224

§ 371 Date: Dec. 21, 2018

(30) Foreign Application Priority Data
Sep. 21, 2018 (CN) 201821576369.7

(51) Int. Cl. G09G 3/34; H03H 11/30

(52) U.S. Cl. CPC G09G 3/34; G09G 2310/0264; H03H 11/30

(57) ABSTRACT

An impedance difference compensation circuit, a display panel and a mobile terminal, the impedance difference compensation circuit is applied in a display panel driving circuit and includes a resistance device, wherein, the resistance device includes at least one resistance.

### CROSS-REFERENCE TO RELATED APPLICATION

This application is the PCT Application No. PCT/CN2018/1152224 for entry into US national phase, with an international filing date of Nov. 13, 2018 designating US, now pending, and claims priority to Chinese Patent Application No. 201821576369.7, filed on Sep. 21, 2018, the content of which is incorporated herein by reference in its entirety.

### TECHNICAL FIELD

The present disclosure pertains to the field of display technology, and more particularly to an impedance difference compensation circuit, a display panel and a mobile terminal.

### BACKGROUND

In a display driving circuit of the traditional technology, for each path of image signals, the lengths of transmission paths between signal transmission paths and display wirings are different, equivalent parameters between the signal transmission paths and the corresponding display wirings are different, and a phenomenon that image signals received by different display wirings in the display panel are inconsistent occurs; at this time, the display panel may display uneven images; as a consequence, difference exists in equivalent parameters in the signal transmission paths in the prior art, so that the definition of the image in the display panel may be reduced and user experience is poor.

### SUMMARY

An object of the present disclosure is to provide an impedance difference compensation circuit, a display panel and a mobile terminal, which includes but is not limited to solve a technical problem that transmission efficiency and transmission time of various signals are inconsistent for the reason that equivalent parameters of various signal transmission paths in the display panel driving circuit are different.

In order to solve the technical problem described above, the technical solution to be adopted by the embodiments of the present disclosure is as follows:

an impedance difference compensation circuit, which is applied in a display panel driving circuit, the display panel driving circuit includes:

a drive integrated circuit, including multiple signal transmission channels respectively configured to access drive signals and being arranged at intervals;

a first signal processing circuit electrically connected with the multiple signal transmission channels respectively and configured to respectively transmit the multiple drive signals;

a second signal processing circuit electrically connected with the first signal processing circuit and configured to perform integrated conversion on the multiple drive signals; and

a signal transmission circuit electrically connected with the second signal processing circuit, wherein the signal transmission circuit comprises multiple display wirings which are configured to output the drive signals and are arranged in array, and wherein the signal transmission channels are arranged corresponding to the display wirings respectively;

where the impedance difference compensation circuit includes a resistance device, the resistance device is connected in series or in parallel to an input of the first signal processing circuit and is arranged to enable equivalent resistances between the multiple signal transmission channels and the multiple display wirings be identical; and

where the resistance device comprises at least one resistor.

Another object of the present disclosure is to provide a display panel, including:

a drive integrated circuit which includes multiple signal transmission channels respectively configured to access drive signals and being arranged at intervals;

a first signal processing circuit electrically connected with the multiple signal transmission channels respectively and configured to transmit the multiple drive signals respectively;

a second signal processing circuit electrically connected with the first signal processing circuit and configured to perform integrated conversion on the multiple drive signals; and

a signal transmission circuit electrically connected with the second signal processing circuit, wherein the signal transmission circuit comprises multiple display wirings which are configured to output the drive signals and are arranged in array, wherein the multiple signal transmission channels are arranged corresponding to the multiple display wirings respectively;

a video display circuit electrically connected with the signal transmission circuit and configured to perform video display according to the multiple drive signals; and

a resistance device connected in series or in parallel with an input of the first signal processing circuit and configured to enable equivalent resistances between the multiple signal transmission channels and the multiple display wirings be identical; wherein the resistance device comprises at least one resistor.

Another object of the present disclosure is to provide a mobile terminal, including:

a signal collector configured to generate multiple drive signals according to image information; and

a display panel collected with the signal collector and configured to perform video display according to the multiple drive signals;

where the display panel comprises:

a drive integrated circuit, including multiple signal transmission channels respectively configured to receive drive signals and being arranged at intervals;

a first signal processing circuit electrically connected with the multiple signal transmission channels respectively and configured to transmit the multiple drive signals respectively;

a second signal processing circuit electrically connected with the first signal processing circuit and configured to perform integrated conversion on the multiple drive signals; and

a signal transmission circuit electrically connected with the second signal processing circuit, wherein the signal transmission circuit comprises multiple display wirings which are configured to output the drive signals and are arranged in array, wherein the multiple signal transmission channels are arranged corresponding to the multiple display wirings respectively;

a video display circuit electrically connected with the signal transmission circuit and configured to perform video display according to the multiple drive signals; and

a resistance device connected in series or in parallel with an input of the first signal processing circuit and configured to enable equivalent resistances between the multiple signal transmission channels and the multiple display wirings be identical; wherein the resistance device comprises at least one resistor.

The impedance difference compensation circuit provided by the embodiments of the present disclosure compensates the impedance difference in each of the signal transmission paths through the resistance device to enable equivalent resistances in each of the signal transmission paths to be identical, all display wirings may receive the multiple drive signals which are completely consistent, the display panel displays uniform images according to these multiple drive signals which are completely consistent; in the present disclosure, the specific circuit structures of the various circuit modules in the display panel driving circuit need not to be changed, the equivalent resistances in each of the signal transmission paths may be kept consistent through the resistance device, and a problem that there is difference in the equivalent resistances of the signals transmission paths in the display panel driving circuit in the exemplified technology is solved.

### BRIEF DESCRIPTION OF DRAWINGS

In order to explain the embodiments of the present disclosure more clearly, a brief introduction regarding the accompanying drawings that need to be used for describing the embodiments or the prior art is given below; it is obvious that the accompanying drawings described as follows are only some embodiments of the present disclosure; for the person of ordinary skill in the art, other drawings may also be obtained according to the current drawings on the premise of paying no creative labor.

FIG. 1 illustrates a modular structural diagram of a display panel driving circuit provided by an embodiment of the present disclosure;

FIG. 2 illustrates an application framework diagram of an impedance difference compensation circuit provided by an embodiment of the present disclosure;

FIG. 3 illustrates an application framework diagram of another impedance difference compensation circuit provided by an embodiment of the present disclosure;

FIG. 4 illustrates a circuit configuration diagram of a resistance device provided by an embodiment of the present disclosure;

FIG. 5 illustrates a circuit configuration diagram of another resistance device provided by an embodiment of the present disclosure;

FIG. 6 illustrates a circuit configuration diagram of another resistance device provided by an embodiment of the present disclosure;

FIG. 7 illustrates a circuit configuration diagram of another resistance device provided by an embodiment of the present disclosure;

FIG. 8 illustrates a modular structural diagram of a display panel provided by an embodiment of the present disclosure;

FIG. 9 illustrates a modular structural diagram of a mobile terminal provided by an embodiment of the present disclosure; and

FIG. 10 illustrates a modular structural diagram of an impedance difference compensation system of a display panel driving circuit provided by an embodiment of the present disclosure.

### DETAILED DESCRIPTION

In order to make the purpose, the technical solution and the advantages of the present disclosure be clearer and more understandable, the present disclosure will be further described in detail below with reference to accompanying figures and embodiments. It should be understood that the specific embodiments described herein are merely intended to illustrate but not to limit the present disclosure.

It should be noted that, when one component is described to be “fixed to” or “arranged on” another component, this component may be directly or indirectly arranged on another component. When one component is described to be “connected with” another component, it may be directly or indirectly connected to the other component. Orientation or position relationships indicated by terms including “upper”, “lower”, “left” and “right” are based on the orientation or position relationships shown in the accompanying figures and is only used for the convenience of description, instead of indicating or implying that the indicated device or element must have a specific orientation and is constructed and operated in a particular orientation, and thus should not be interpreted as limitation to the present disclosure. For the person of ordinary skill in the art, the specific meanings of the aforesaid terms may be interpreted according to specific conditions. Terms of “the first” and “the second” are only for the purpose of describing conveniently and should not be interpreted as indicating or implying relative importance or impliedly indicating the number of indicated technical features. “Multiple/a plurality of” means two or more unless there is an additional explicit and specific limitation.

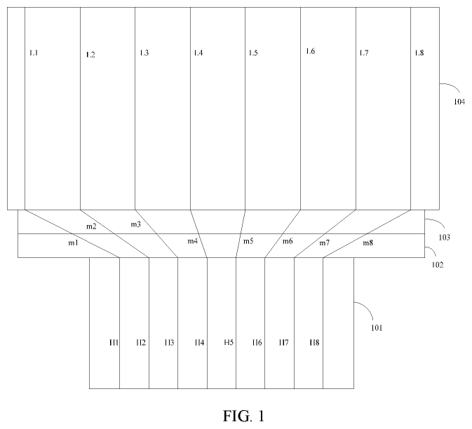

It should be noted that, according to transmission principle and characteristic of image data in a display panel, when a display panel driving circuit is connected with multiple drive signals, where the drive signals include a large amount of image data, the drive signals are transmitted and converted through the display panel driving circuit, then, the display panel is driven to display high-definition images through the multiple drive signals so as to meet the viewing requirement of the user. FIG. 1 illustrates a modular structure of a display panel driving circuit provided by an embodiment of the present disclosure, as shown in FIG. 1, the display panel driving circuit includes: a drive integrated circuit 101, a first signal processing circuit 102, a second signal processing circuit 103 and a signal transmission circuit 104; where the drive integrated circuit 101 includes multiple signal transmission channels, the drive signals may be accessed through the multiple signal transmission channels respectively, and the multiple signal transmission channels are arranged at intervals; optionally, the multiple signal transmission channels are arranged to be distributed at equal intervals in the drive integrated circuit, so that drive signals may be stably transmitted by each of the signal transmission channels, an integration level of electronic components in the drive integrated circuit 101 of the embodiment is improved, and a space layout in the drive integrated circuit 101 is simplified; exemplarily, as shown in FIG. 1, the drive integrated circuit 101 includes eight signal transmission channels of H1, H2 . . . H7 and H8, where, one path of drive signal may be accessed through each of the signal transmission channels, then, eight drive signals may be accessed by the drive integrated circuit 101 simultaneously, the display panel driving circuit may drive the display panel to display images in real time through these display panel driving circuits. Therefore, in the embodiment of the present disclosure, multiple drive signals may be accessed in real-time through the drive integrated circuit 101 so as to implement data interaction between the display panel and external electronic equipment; moreover, each of the signal transmission channels in the drive integrated circuit 101 may be kept at an independent signal transmission state and has no influence on each other, so that the safety and the rate of signal transmission in the embodiment of the present disclosure are greatly improved; the drive integrated circuit 101 may access a large amount of image data quickly, thereby enhancing an efficiency and an application range of signal transmission in the display panel driving circuit.

The first signal processing circuit 102 is electrically connected with each of the signal transmission channels, the drive integrated circuit 101 transmits multiple drive signals to the first signal processing circuit 102, the first signal processing circuit 102 has a signal transmission function and is configured to transmit the multiple drive signals respectively; the first signal processing circuit 102 has characteristics of low signal transmission error rate, high transmission rate and extremely high compatibility due to the fact that a signal transmission chip and a flexible substrate circuit are integrated on the first signal processing circuit 102; the first signal processing circuit 102 serves as a signal transmission link between different circuit modules, the first signal processing circuit 102 may keep the integrity of data in the signals completely; thus, multiple drive signals may be transmitted to the second signal processing circuit 103 through the first signal processing circuit 102, the drive signals may be transmitted in the display panel driving circuit rapidly and completely. The first signal processing circuit 102 in the embodiment of the present disclosure reduces errors of drive signals in the transmission process, enhances the compatibility of the display panel driving circuit, and saves a manufacturing cost of the display panel driving circuit.

The second signal processing circuit 103 is connected with the first signal processing circuit 102, the first signal processing circuit 102 transmits the multiple drive signals to the second signal processing circuit 103, the second signal processing circuit 103 performs integrated conversion on the multiple drive signals to enhance an image drive capacity of the drive signals, so that the display panel may be driven to display high-definition images having higher image quality through the multiple drive signals; where the second signal processing circuit 103 is a sector centralized processing circuit and has the function of implementing centralized conversion and processing of signals, so that an information interaction among signals of different paths may be realized, and a complexity degree of the circuit function achieved by multiple paths of signals is improved, so that the multiple drive signals as output by the second signal processing circuit 103 may drive the electronic circuit to achieve more complex operations; in the embodiment of the present disclosure, since the multiple drive signals as output by the first signal processing circuit 102 are independent from each other, each path of drive signal may achieve a specific function in the display panel, the multiple drive signals may be integrated and converted through the second signal processing circuit 103, such that the multiple drive signals may be matched with each other to achieve overall circuit function, the display panel displays a dynamic and clear image according to the multiple drive signals, which enables the display panel in the embodiment of the present disclosure to process and receive different types of image data, so that the user has better viewing experience, and an actual different viewing requirements of the user may be met through the images in the display panel.

It should be noted that, both the specific circuit structure of the first signal processing circuit 102 and the specific circuit structure of the second signal processing circuit 103 are the circuit structure in the exemplary technology; for example, the first signal processing signal 102 is a COF (Chip On Flex) circuit in the traditional display panel field; the first signal processing circuit 102 includes an electronic device such as a rectifier and a logic gate, conversion among signals of different amplitudes, and signal transmission control may be realized through the rectifier and the logic gate, so that when the first signal processing circuit 102 accesses different types of drive signals, the first signal processing circuit 102 may enable the drive signals to be mutually transmitted among different circuit modules through conversion and transmission functions of electronic components in the first signal processing circuit 102; for another example, the second signal processing circuit 103 is a fan-out circuit in the traditional display panel field, the second signal processing circuit 103 includes electronic devices including a plurality of MOS (Metal Oxide Semiconductor) tubes and a plurality of diodes, where the plurality of MOS tubes are distributed in an array on PCB (Printed Circuit Board), when the MOS tube array in the second signal processing circuit 103 accesses multiple drive signals, the plurality of MOS tubes and the plurality of diodes may perform an integrated processing on the multiple drive signals by controlling switch on or switch off of the MOS tube, such that the multiple drive signals as output by the second signal processing circuit 103 may be used as a whole function to drive the display panel to display clearer and more complex images.

The signal transmission circuit 104 is electrically connected with the second signal processing circuit 103, the second signal processing circuit 103 transmits the multiple drive signals to the signal transmission circuit 104, the multiple drive signals may be rapidly transmitted through the signal transmission circuit 104, so that the display panel may receive image data in real time; where the signal transmission circuit 104 includes: multiple display wirings in an arrangement of array, and the multiple display wirings are distributed at equal intervals in the signal transmission circuit 104, image data may be received uniformly by the display panel through the arrangement mode of the display wirings, so that pictures presented by the display panel are more stable and more coordinated; as a consequence, the drive signals may be output through the display wirings, then, image data are transmitted, and good viewing experience is brought to the user by the display panel; as shown in the signal transmission circuit 104 of FIG. 1, the signal transmission circuit 104 includes eight display wirings of L1, L2 . . . L7, L8, where each display wiring is configured to transmit one path of drive signal, eight paths of drive signals may be transmitted simultaneously through the eight display wirings, then, the display panel may be driven to perform dynamic display of images in real time through the drive signals in the display wirings to ensure that the display panel operates in a stable working state.

Where, in the embodiment of the present disclosure, the signal transmission channels are arranged corresponding to the display wirings respectively, so that when the signal transmission channel accesses the drive signal, a flow of a transmission path of each path of drive signal is: the signal transmission channel, the first signal processing circuit 102, the second signal processing circuit 103 and the display wiring, the display panel receives the drive signals through the display wirings, and the display panel may be driven to operate in a normal working state in real time through the drive signals, the display panel may display high-definition images in real time so as to meet people's viewing requirements; however, according to the module structure of the display panel driving circuit as shown in FIG. 1, the multiple signal transmission channels are arranged at intervals, and the multiple display wirings are arranged in array; therefore, in the transmission paths of drive signals, each signal transmission channel has a unique relative position with respect to the corresponding display wiring; then, in the multiple signal transmission paths, distances between the signal transmission channels and the display wirings are not identical, since there are the first signal processing circuit 102 and the second signal processing circuit 103 between the signal transmission channels and the display wirings, when the signal transmission paths of the multiple drive signals are different, the equivalent resistances between the signal transmission channels and the display wirings are also different, so that the speeds, the losses and the transmission time of the drive signals in the signal transmission paths are different. Taking the display panel driving circuit in FIG. 1 as an example, since the driving circuit of the display panel may transmit eight drive signals simultaneously, there exists eight signal transmission paths of m1, m2 . . . m7, m8 in the display panel driving circuit, in the first signal transmission path, the distance between the first signal transmission channel H1 and the first display wiring L1 is the longest, and the equivalent resistance between the first signal transmission channel H1 and the first display wiring L1 is the largest; when an output of the first signal transmission channel H1 outputs a first path of drive signal, the loss and the transmission time of the first drive signal in the signal transmission process are maximum; then, the first display wiring 11 receives the first path of drive signal at the latest; otherwise, in the eight signal transmission paths, the distance between the fourth signal transmission channel H4 and the fourth display wiring L4 is the shortest, and the equivalent resistance between the fourth signal transmission channel H4 and the fourth display wiring L4 is the minimum, so that the loss and the transmission time of the fourth drive signal in the transmission process are minimum, the fourth display wiring L4 may receive a fourth path of drive signal at the earliest, and the like; due to the fact that the equivalent resistances between the multiple signal transmission channels and the corresponding display wirings are different in the transmission process of the multiple paths of drive signals, the multiple drive signals may not be received by so many display wirings simultaneously; then, the display panel may receive the multiple drive signals that are inconsistent, so that the display panel may display uneven images when it is driven by the multiple drive signals, image quality and definition in the display panel may also be greatly reduced, and the feeling of viewing experience of the user is poor.

As described above, since the relative positions between the signal transmission paths and the corresponding display wirings are different in the drive integrated circuit 101 and the signal transmission circuit 104, so that the equivalent resistances between the signal transmission channels and the corresponding display wirings in the signal transmission paths are different, the transmission time of the multiple drive signals in the signal transmission paths is different, the display panel may receive multiple drive signals that are inconsistent, so that there is a problem that images in the display panel are inconsistent and incongruous in the display panel, the real viewing experience of the user is greatly reduced; moreover, if the structure of the display panel driving circuit is more complex, when the number of paths of the drive signals transmitted by the display panel driving circuit increases, differences in the equivalent resistances in the signal transmission paths may be larger, and a problem that images displayed by the display panel are seriously asymmetrical may occur; therefore, the aforesaid display panel driving circuit may not be widely used in different types of display panels, and particularly in large-scale and wide-screen display panels, which results in a low practicability of the display panel driving circuit in the embodiment of the present disclosure.

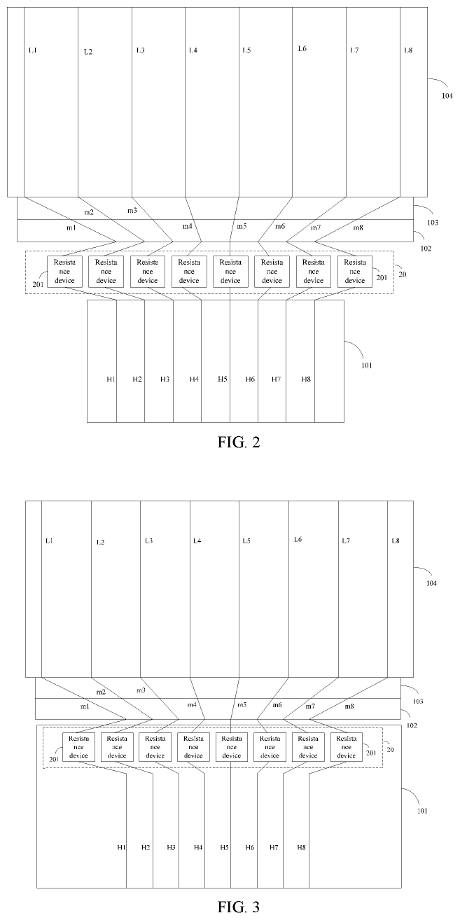

Aiming at the problem that there is difference in signal transmission of the display panel driving circuit in FIG. 1, the present disclosure provides an impedance difference compensation circuit 20, where the impedance difference compensation circuit 20 is applied in the display panel driving circuit, the multiple drive signals may be kept consistent in the transmission process through the impedance difference compensation circuit 20, and the equivalent resistances between the signal transmission channels and the corresponding display wirings are identical, so that each of the display wirings may receive consistent drive signals, the display panel displays even images according to the multiple drive signals. Particularly, FIG. 2 illustrates an application framework of an impedance difference compensation circuit 20 according to an embodiment of the present disclosure, as shown in FIG. 2, the impedance difference compensation circuit 20 includes a resistance device 201, where the resistance device 201 is connected in series or in parallel to an input of the first signal processing circuit 102, the equivalent resistance between the signal transmission channel and the corresponding display wiring may be adjusted through the resistance device 201, in this way, the equivalent resistances between the multiple signal transmission channels and the multiple display wirings are identical, so that losses and transmission time of the drive signals in the transmission process are identical, the multiple drive signals may be received by the multiple display wirings simultaneously, the display panel may display clear and consistent images to improve the viewing effect of the user when it is driven by the drive signals.

In the impedance difference compensation circuit 20 as shown in FIG. 2, the resistance device 201 includes at least one resistor, and an equivalent resistance of an output of each signal transmission channel may be adjusted through the resistance, such that the losses and the transmission rates of the drive signals in each path of signal transmission paths are kept the same;

exemplarily, as shown in FIG. 2, the display panel driving circuit may access eight drive signals simultaneously, where the equivalent resistance between the first signal transmission channel H1 and the first display wiring L1 is the largest in the first signal transmission path m1, the equivalent resistance in the first signal transmission path m1 is reduced through the resistance device 201; the fourth signal transmission path m4 is the shortest, and the resistance between the fourth signal transmission channel H4 and the fourth display wiring L4 is the minimum, the equivalent resistance in the fourth signal transmission path m4 is increased through the resistance device 201; in this way, the equivalent resistances of eight signal transmission paths in the display panel driving circuit may be kept consistent through the resistance device 201, so that all of the display wirings may receive completely consistent drive signals, which enables the display panel to display uniform and complete images to meet the viewing requirement of the user.

Therefore, in the application framework shown in FIG. 2, the equivalent resistances between the multiple signal transmission channels and the corresponding display wirings may be identical through the resistance device 201, the display panel driving circuit may simultaneously receive multiple drive signals and simultaneously output multiple drive signals, the drive signals are kept consistent in different signal transmission paths, so that the display panel may be driven to display completely uniform images through the consistent drive signals to improve practical performance of the display panel driving circuit; therefore, according to the embodiment of the present disclosure, the impedance difference compensation circuit 20 is connected to an input of the drive integrated circuit 101, the equivalent resistance differences in the multiple signal transmission paths may be compensated through the impedance difference compensation circuit 20, so that the equivalent resistances between the multiple signal transmission channels and the corresponding display wirings are kept consistent, the multiple display wirings may receive the completely consistent drive signals, the structure is simple, the impedance difference compensation circuit 20 may be applied in different types of display panels, the display panel may display uniform and coordinated images to enhance the real experience feeling of viewing of the user, thereby effectively solving the problem that the drive signals received by the display panel are inconsistent, images displayed by the display panel is uneven, and the viewing experience of the user is poor due to the difference of equivalent parameters in the multiple signal transmission paths of the display panel driving circuit in the exemplary technology.

As an optional implementation mode, as shown in FIG. 2, the impedance difference compensation circuit 20 is arranged on a wiring between the drive integrated circuit 101 and the first signal processing circuit 102, the resistance device 201 on each signal transmission path is arranged at the external of the drive integrated circuit 101, so that the equivalent resistances on the signal transmission paths are enabled to be identical through the resistance device 201, and the multiple display wirings may receive the completely consistent drive signals to reduce incoordination and nonuniformity of images in the display panel effectively.

As an optional implementation mode, FIG. 3 illustrates an application framework of an impedance difference compensation circuit 20 according to an embodiment of the present disclosure, as compared to the application framework of the impedance difference compensation circuit 20 in FIG. 2, in FIG. 3, the impedance difference compensation circuit 20 is arranged in the drive integrated circuit 20, the equivalent resistances between the multiple signal transmission channels and the corresponding display wirings may be enabled to be completely identical through the resistance device 201 in the transmission process of the drive signals, so that the display panel may display clearer and real images; besides, the resistance device 201 is arranged inside the drive integrated circuit 20, which facilitates simplifying the circuit structure in the display panel, and enabling the structure of the display panel driving circuit be more integrated and miniaturized. The impedance difference compensation circuit 20 in the embodiment of the present disclosure has lower application cost and is prone to be realized, and a practicability of the impedance difference compensation circuit 20 and a use experience of the display panel are effectively improved.

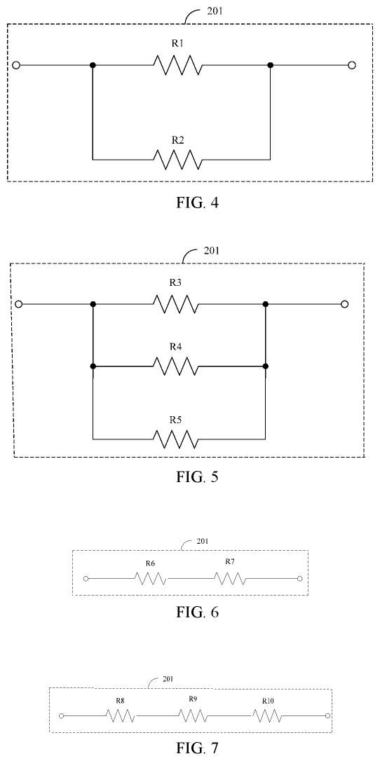

As an optional implementation mode, FIG. 4 illustrates a circuit structure of the resistance device 201 provided by an embodiment of the present disclosure, as shown in FIG. 4, where the resistance device 201 includes two resistors connected in parallel, and the two resistors connected in parallel are a first resistor R₁ and a second resistor R₂ respectively; the first resistor R₁ and the second resistor R₂ are connected in parallel; a first end of the first resistor R₁ and a first end of the second resistor R₂ are in common connection with a signal transmission channel and are configured to access the drive signal, a second end of the first resistor R₁ and a second end of the second resistor R₂ are in common connection with the first signal processing circuit 102 and are configured to transmit the drive signal to the first signal processing circuit 102; and a resistance value of the first resistor R₁ and a resistance value of the second resistor R₂ meet the following conditions:

$$\frac{1}{{R}_{1}} + \frac{1}{{R}_{2}} = \frac{1}{{R}_{0}} \qquad ( 1 )$$

in aforesaid formula, R₁ represents the resistance value of the first resistor R₁, R₂ represents the resistance value of the second resistor R₂, R₀ represents a preset equivalent parameter; it needs to be explained that, R₀ is preset equivalent parameter, and the value of R₀ is set according to the equivalent resistances between the first signal processing circuit 102 and the second signal processing circuit 102 in each of the signal transmission paths; for example, R₀ is set to be 100 ohms; therefore, in the embodiment of the present disclosure, the resistance device 201 may enable the equivalent resistances between the multiple signal transmission channels and the corresponding display wirings to be kept the same according to the resistance value of the first resistor R₁ and the second resistor R₁ connected in parallel, the multiple drive signals have the same transmission speed and transmission time in the signal transmission process, the display wirings may receive the completely consistent drive signals, and the operation is simple and convenient.

As an optional implementation mode, FIG. 5 illustrates another circuit structure of the resistance device 201 according to an embodiment of the present disclosure, as shown in FIG. 5, the resistance device 201 includes three resistors connected in parallel, and the three resistors connected in parallel are a third resistor R₃, a fourth resistor R₄ and a fifth resistor R₅ respectively, where a first end of the third resistor R₃, a first end of the fourth resistor R₄ and a first end of the fifth resistor R₅ are connected in common with the signal transmission channel, a second end of the third resistor R₃, a second end of the fourth resistor R₄ and a second end of the fifth resistor R₅ are connected in common with the first signal processing circuit 102, and the resistance value of the third resistor R₃, the resistance value of the fourth resistor R₄ and the resistance value of the fifth resistor R₅ meet the following conditions:

$$\frac{1}{{R}_{3}} + \frac{1}{{R}_{4}} + \frac{1}{{R}_{5}} = \frac{1}{{R}_{0}} \qquad ( 2 )$$

In aforesaid formula (2), R₃ represents the resistance value of the third resistor R₃, R₄ represents the resistance value of the fourth resistor R₄, R₅ represents the resistance value of the fifth resistor R₅, R₀ represents the preset equivalent parameter; wherein the value of R₀ is set according to the equivalent resistance between the first signal processing circuit 102 and the second signal processing circuit 103 in each signal transmission path, therefore, in this embodiment of the present disclosure, the resistance device 201 is configured to enable the equivalent resistance between each signal transmission channel and the corresponding display wiring to be identical according to a parallel resistance value of the third resistor R₃, the fourth resistor R₄ and the fifth resistor R₅ connected in parallel, thereby implementing dynamically compensating impedance difference in each of the signal transmission paths to improve consistency of images in the display panel.

In combination with the specific circuit structure of the resistance device 201 shown in FIGS. 4 and 5, the resistance device 201 includes a plurality of resistors connected in parallel, the equivalent resistance in each signal transmission path may be changed correspondingly by adjusting the parallel resistance value of the resistance device 201, so that the equivalent resistances between the multiple signal transmission channels and the corresponding display wirings are completely identical; the resistance device 201 is simple in circuit structure and is prone to be implemented, manufacturing cost and industrial application cost of the impedance difference compensation circuit 20 are greatly reduced, the impedance difference in each signal transmission path may be effectively compensated, and the consistency of the drive signals output by the display panel driving circuit is improved.

It may be understood that, since FIG. 4 and FIG. 5 are only examples of the resistance device 201 and is not constituted as technical limitation to the resistance device 201 in the embodiment of the present disclosure, in a practical application process, a technical personal may use four resistors connected in parallel or five resistors connected in parallel to achieve a circuit function realized by the resistance device 201; thus, the resistance device 201 in the embodiment of the present disclosure has a very flexible circuit structure and further improves the compatibility of the impedance difference compensation circuit 20, the impedance difference compensation circuit 20 may be applied to various types of display panels to compensate the impedance differences of the signal transmission paths in the display panel driving circuit, so that the display panel may be effectively ensured to display uniform and high-quality images or videos to the user, the practicability is extremely high.

As an optional embodiment mode, FIG. 6 illustrates another circuit structure of the resistance device 201 provided by the embodiment of the present disclosure, as shown in FIG. 6, where, the resistance device 201 includes two resistors connected in series, and the two resistors connected in series are a sixth resistor R₆ and a seventh resistor R₇ respectively; where a first end of the sixth resistor R₆ is connected with a signal transmission channel, a second end of the sixth resistor R₆ is connected with a first end of the seventh resistor R₇, and a second end of the seventh resistor R₇ is connected with the first signal processing circuit 102, and a resistance value of the sixth resistor R₆ and a resistance value of the seventh resistor R₇ meet the following conditions:

R₆+R₇=R₀ (3)

in aforesaid formula (3), R₆ represents the resistance value of the sixth resistor R₆, R₇ represents the resistance value of the sixth resistor R₇, R₀ represents the preset equivalent parameter, where, R₀ represents the preset equivalent parameter in each of the signal transmission paths; in this embodiment of the present disclosure, the resistance device 201 may adjust the equivalent resistance between each signal transmission channel and the corresponding display wiring by two resistors connected in parallel (including the sixth resistor R₆ and the seventh resister R₇), the circuit structure is simple and is prone to be implemented, such that each drive signal in the display panel driving circuit has the same transmission time and loss in the transmission process, the display panel may receive multiple drive signals which are completely consistent, so that the display panel may dynamically display completely consistent and coordinated images or videos.

As an optional implementation mode, FIG. 7 illustrates another circuit structure of a resistance device 201 according to an embodiment of the present disclosure, as shown in FIG. 7, the resistance device 201 includes three resistors connected in series, and the three resistors connected in series are an eighth resistor R₈, a ninth resistor R₉ and a tenth resistor R₁₀ respectively; where a first end of the eighth resistor R8 is connected with the signal transmission channel, a first end of the ninth resistor R₉ is connected with a second end of the eighth resistor R₈, a second end of the ninth resistor R₉ is connected with a first end of the tenth resistor R₁₀, a second end of the tenth resistor R₁₀ is connected with the first signal processing circuit 102, and a resistance value of the ninth resistor R₈, a resistance value of the ninth resistor R₉ and a resistance value of the tenth resistor R₁₀ meet the following conditions:

R₈+R₉+R₁₀=R₀ (4)

In aforesaid formula (4), R₈ represents the resistance value of the eighth resistor R₈, R₉ represents the resistance value of the ninth resistor R₉, R₁₀ represents the resistance value of the tenth resistor R₁₀, R₀ represents the preset equivalent parameter, where R₀ is the equivalent parameter preset by the technical personnel; thus, the resistance device 201 in the embodiment of the present disclosure may enable the equivalent resistances in the multiple signal transmission paths of the display panel to be identical through three resistors connected in parallel (including the eighth resistor R₈, the ninth resistor R₉, the tenth resistor R₁₀), each of the display wirings in the signal transmission circuit 104 may receive completely consistent drive signal, so that a problem of nonuniformity and incoordination of images due to impedance differences of the drive signals in the transmission process may be avoided, and the practicability of the display panel driving circuit is greatly improved.

It should be noted that, since the specific circuit structure of the resistance device 201 shown in FIGS. 6 and 7 is only an example of the present disclosure, but is not constituted as technical limitation to the impedance difference compensation circuit 20 in the present disclosure; in an practical application process, the resistance device 201 may adjust the equivalent resistance between each signal transmission channel and the corresponding display wiring by connecting four or five resistors connected in series, so that the equivalent resistances in the multiple signal transmission paths are kept the same, the user may enjoy uniform and coordinate images through the display panel; besides, the resistance device 201 has a very flexible circuit structure, the user may adjust the specific circuit structure of the resistance device 201 according to the number and the specific functions of the drive signals, the compatibility is extremely high, the resistance device 201 may be applied to different types of display panels, good viewing experience is brought to the user, and the practical value of the display panel is improved.

As an optional embodiment, in the aforesaid drive integrated circuit 101, the signal transmission channel includes a buffer; when the signal traditional channel is communicated with a drive signal, the drive signal may be stored temporarily through the buffer to avoid occurrence of loss of image data when the drive signals are transmitted in the signal transmission channel; due to the fact that, the display panel driving circuit needs to access large-capacity image data in real time through the signal transmission channels in the process of displaying images using the display panel, the drive signals may be cached and retained in real time through the buffer, and large amount of drive signals may be accessed rapidly through the signal transmission channels, the signal transmission capability of the display panel driving circuit in the embodiment of the present disclosure is improved, so that the display panel is enabled to dynamically display images or videos according to the drive signals to meet the actual requirements of the user.

As an optional embodiment, the number of the signal transmission channels is equal to the number of the display wirings in the drive integrated circuit 101 and the signal transmission circuit 104; for example, the drive integrated circuit 101 includes eight signal transmission channels, the signal transmission circuit 104 also includes eight display wirings; in combination with what described above, since the signal transmission channels are corresponding one-to-one to the display wirings respectively, then, in the embodiment of the present disclosure, a transmission path of each path of drive signal includes a signal transmission channel and a display wiring, there are no redundant signal transmission channels or redundant display wirings in the display panel driving circuit, and a problem of mismatching of signal transmission in the drive integrated circuit 101 and the signal transmission circuit 104 is avoided, the signal transmission efficiency of the display panel driving circuit in the embodiment of the present disclosure is greatly improved, and a problem of a waste of electronic components in the display panel driving circuit is avoided.

FIG. 8 illustrates a modular structure of a display panel 50 provided by an embodiment of the present disclosure, as shown in FIG. 8, the display panel 50 includes a drive integrated circuit 101, a resistance device 201, a first signal processing circuit 102, a second signal processing circuit 103, a signal transmission circuit 104 and a video display circuit 501; where the drive integrated circuit 101 includes multiple signal transmission channels which are respectively configured to access drive signals and are arranged at intervals; the resistance device 201 is connected in series or in parallel to an input of the first signal processing circuit 102, the equivalent resistances of the drive signals in the transmission paths may be adjusted through the resistance device 201, and the resistance device 201 includes at least one resistor; each signal transmission channel is connected with the first signal processing circuit 102 through the resistance device 201, the multiple drive signals may be transmitted through the first signal processing circuit 102 respectively; the second signal processing circuit 103 is electrically connected with the first signal processing circuit 102, the second signal processing circuit 103 may perform integrated conversion on the multiple drive signals; the signal transmission circuit 104 is electrically connected with the second signal processing circuit 103, the signal transmission circuit 104 includes multiple display wirings configured to output the drive signals and are arranged in array; where the signal output channels are arranged to correspond to the display wirings respectively; the video display circuit 501 is connected with the signal transmission circuit 104, when the signal transmission circuit 104 transmits multiple drive signals to the video display circuit 501, the video display circuit 501 performs a video display according to the multiple drive signals; since the video display circuit 501 may receive and identify the drive signals, the video display circuit 501 may decode the drive signals and obtain corresponding image data, and then display corresponding dynamic images to meet the requirements of viewing experience of the user; as an optional embodiment mode, the video display circuit 501 is a video signal display circuit in the exemplary technology, where the traditional video display circuit includes electronic components such as an LED (Light Emitting Diode), a MOS (Metal Oxide Semiconductor) tube, a resistor and the like, when the drive signals are received by the video display circuit 501, the drive signals may drive the LED to emit corresponding light source, and the color and the brightness of a light source in the LED may be adjusted through the drive signals, so that the user may enjoy dynamic images through the video signal display circuit, and good viewing experience is brought to the user.

As an optional embodiment, the resistance device 201 is arranged in the drive integrated circuit 101; or as an alternative, the resistance device 201 is arranged on a wiring between the drive integrated circuit 101 and the first signal processing circuit 102.

As an optional embodiment, where the resistance device 201 includes two resistors connected in parallel, and the two resistors connected in parallel are an eleventh resistor R₁₁ and a twelfth resistor R₁₂ respectively.

Where, a first end of the eleventh resistor R₁₁ and a first end of the twelfth resistor R₁₂ are in common connection with the signal transmission channel, a second end of the eleventh resistor R₁₁ and a second end of the twelfth resistor R₁₂ are in common connection with the first signal processing circuit 102, and a resistance value of the eleventh resistor R₁₁ and a resistance value of the twelfth resistor R₁₂ meet the following conditions:

$$\frac{1}{{R}_{11}} + \frac{1}{{R}_{12}} = \frac{1}{{R}_{0}} \qquad ( 5 )$$

In aforesaid formula (5), R₁₁ represents the resistance value of the eleventh resistor R₁₁, R₁₂ represents the resistance value of the twelfth resistor R₁₂, R₀ represents the preset equivalent parameter.

As an optional implementation mode, the resistance device 201 includes three resistors connected in parallel, and the three resistors connected in parallel are a thirteenth resistor R₁₃, a fourteenth resistor R₁₄ and a fifteenth resistor R₁₅ respectively, where a first end of the thirteenth resistor R₁₃, a first end of the fourteenth resistor R₁₄ and a first end of the fifteenth resistor R₁₅ are in common connection with the signal transmission channel, a second end of the thirteenth resistor R₁₃, a second end of the fourteenth resistor R₁₄ and a second end of the fifteenth resistor R₁₅ are in common connection with the first signal processing circuit 102, and a resistance value of the thirteenth resistor R₁₃, a resistance value of the fourteenth resistor R₁₄ and a resistance value of the fifteenth resistor R₁₅ meet the following conditions:

$$\frac{1}{{R}_{13}} + \frac{1}{{R}_{14}} + \frac{1}{{R}_{15}} = \frac{1}{{R}_{0}} \qquad ( 6 )$$

In aforesaid formula (6), R₁₃ represents the resistance value of the thirteenth resistor R₁₃, R₁₄ represents the resistance value of the fourteenth resistor R₁₄, R₁₅ represents the resistance value of the thirteenth resistor R₁₅, R₀ represents the preset equivalent parameter.

As an optional implementation mode, where the resistance device 201 includes two resistors connected in series, and the two resistors connected in series are a sixteenth resistor R₁₆ and a seventeenth resistor R₁₇ respectively.

Where a first end of the sixteenth resistor R₁₆ is connected with a signal transmission channel, a second end of the sixteenth resistor R₁₆ is connected with a first end of the seventeenth resistor R₁₇, a second end of the seventeenth resistor R₁₇ is connected with the first signal processing circuit 102, and a resistance value of the sixteenth resistor R₁₆ and a resistance value of the seventeenth resistor R₁₇ meet the following condition:

R₁₆+R₁₇=R₀ (7)

In aforesaid formula (7), R₁₆ represents the resistance value of the sixteenth resistor R₁₆, R₁₇ represents the resistance value of the seventeenth resistor R₁₇, R₀ represents the preset equivalent parameter.

As an optional implementation mode, where the resistance device 201 includes three resistors connected in series, and the three resistors connected in series are an eighteenth resistor R₁₈, a nineteenth resistor R₁₉ and a twentieth resistor R₂₀ respectively.

A first end of the eighteenth resistor R₁₈ is connected with the signal transmission channel, a second end of the eighteenth resistor R₁₈ is connected with a first end of the nineteenth resistor R₁₉, a second end of the nineteenth resistor R₁₉ is connected with a first end of the twentieth resistor R₂₀, a second end of the twentieth resistor R₂₀ is connected with the first signal processing circuit 102, and a resistance value of the eighteenth resistor R₁₈, a resistance value of the nineteenth resistor R₁₉ and a resistance value of the twentieth resistor R₂₀ meet the following conditions:

R₁₈+R₁₉+R₂₀=R₀ (8)

In aforesaid formula (8), R₁₈ represents the resistance value of the eighteenth resistor R₁₈, R₁₉ represents the resistance value of the nineteenth resistor R₁₉, R₂₀ represents the resistance value of the twentieth resistor R₂₀, R₀ represents the preset equivalent parameter.

As an optional implementation mode, where the signal transmission channel includes:

a buffer configured to buffer the drive signals.

As an optional implementation mode, the number of the signal transmission channels is equal to the number of the display wirings.

As an optional implementation mode, the multiple signal transmission channels are distributed at equal intervals in the drive integrated circuit 101, the multiple display wirings are distributed at equal intervals in the signal transmission circuit 104.

It should be noted that, since the display panel 50 in FIG. 8 corresponds to the impedance difference compensation circuit 20, regarding the specific embodiment of the display panel 50 in this embodiment, reference may be made to the embodiments of FIGS. 1-7, it is not repeatedly described herein.

In the embodiment of the present disclosure, since the resistance device 201 is arranged at an input of the first signal processing circuit 102, the equivalent resistances in each of the signal transmission paths may be adjusted through the resistance device 201, so that the equivalent resistances between the signal transmission channels and the display wirings are identical, each of the drive signals has the same transmission rate and the loss of power consumption during the transmission process. The video display circuit 501 receives multiple paths of consistent drive signals, so that the video display circuit 501 may be driven to display uniform and real images in real time through the drive signals, the user may enjoy real and high-definition images through the display panel 50, an effect of viewing experience of the user is greatly improved; therefore, in the embodiment of the present disclosure, the signal transmission paths of the drive signals may have the same equivalent parameters through the resistance device 201 merely, the internal circuit structure and the structure of wiring in the display panel 50 need not to be changed, the video display circuit 501 may receive the completely-consistent multiple drive signals in real time, the display panel 50 may display more real and congruous images or videos, and a problem that impedance difference exists in different signal transmission paths, such that the images displayed in the display panel are uneven, the quality of images or video in the display panel is poor, and the feeling of viewing experience of the user is reduced in the exemplified technology is effectively solved.

As an optional implementation mode, the display panel 50 is a TFT-LCD (Thin Film Transistor Liquid Crystal Display), a LCD (Liquid Crystal Display), an OLED (Organic Light Emitting Diode), or a QLED (Quantum Dot Light Emitting Diode), so that the various types of display panels may display clearer and more uniform images through the resistance device 201, the practicability of the display panel 50 is stronger, the display panel 50 may be applied in various industrial fields so as to meet an actual requirement of the user.

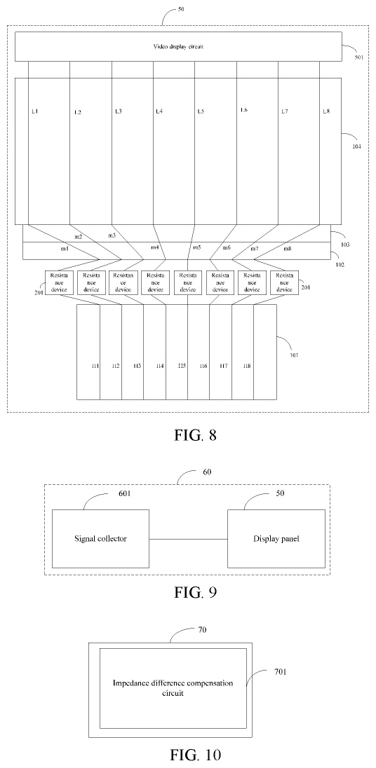

FIG. 9 illustrates a modular structure of a mobile terminal 60 provided by an embodiment of the present disclosure, as shown in FIG. 9, the mobile terminal 60 includes a signal collector 601 and a display panel 50, where the display panel 50 is the display panel 50 shown in the FIG. 8; thus, regarding the specific implementation mode of the display panel 50 in FIG. 9, reference may be made to the embodiment of FIG. 8, it is not repeatedly described herein. The signal collector 601 may collect image information of the outside and generate multiple drive signals according to the image information; the signal collector 601 has the functions of data conversion and signal coding, so that the signal collector 601 performs encoding and conversion on the external image information to obtain a multiple drive signals, the drive signals include large amount of image data, and the drive signals may be rapidly transmitted in the display panel driving circuit; so that the mobile terminal 60 may collect and convert the signals rapidly through the signal collector 601, and a signal transmission efficiency is enhanced.

It should be noted that, the signal collector 601 is a signal acquisition circuit or a signal acquisition chip in the exemplary technology; where the model of the signal acquisition chip is ITUBT601656 or AD7656; the signal acquisition circuit includes electronic components such as an operational amplifier, a resistor, a capacitor and the like, the image information is accessed through a signal input of the signal acquisition circuit, electric energy conversion is achieved through electronic components such as the operational amplifier, the resistor and so on, so that the multiple drive signals may be output in real time through the signal output end of the signal acquisition circuit; in this way, the signal collector 601 in the embodiment of the present disclosure receives the image information in real time and completes signal conversion, the mobile terminal 60 may perform an information interaction operation with external equipment through the signal collector 601.

The display panel 50 is connected with the signal collector 601, the signal collector 601 transmits multiple drive signals to the display panel 50, the display panel 50 performs video display according to the multiple drive signals, the display panel 50 may transmit and decode multiple drive signals to obtain image data, so that the user may watch dynamic and clear images in real time in the display panel 50; where regarding the working principle of the display panel 50 and the internal structure of the display panel 50 in FIG. 9, reference can be made to the embodiment of FIG. 8, it is not repeatedly described herein.

In the modular structure of the mobile terminal 60 shown in FIG. 9, information interaction between the mobile terminal 60 and the external equipment is realized through the signal collector 601, and then the external image information is obtained; when the signal collector 601 transmits multiple drive signals to the display panel 50, and when the drive signals are transmitted in the display panel 50, equivalent impedances in multiple signal transmission paths are identical, so that different drive signals have the same transmission rate and transmission time, multiple drive signals which are completely consistent may be received in the display panel 50, so that the display panel 50 acquires image data comprehensively according to the multiple drive signals, and may display clearer images or videos dynamically; in this way, the mobile terminal 60 in this embodiment may display uniform and coordinate images, the mobile terminal 60 may be applied to different industrial fields to provide the user with high-definition images or videos, and thus has high practical value, and a problem that the mobile terminal may not be widely applied for the reason that videos displayed in the mobile terminal is uneven and incongruous in the exemplary technology is solved effectively.

As an optional implementation mode, the mobile terminal 60 is a mobile phone or a tablet computer; thus, the display panel 50 is applied in the mobile phone or in the tablet computer, so that different actual requirements of the user are met, and use experience of the user is improved.

FIG. 10 illustrates a modular structure of an impedance difference compensation system 70 of a display panel driving circuit provided by an embodiment of the present disclosure, as shown in FIG. 10, the impedance difference compensation system 70 of the display panel driving circuit includes the impedance difference compensation circuit 701; where the impedance difference compensation circuit 701 is applied in the display panel driving circuit, regarding the specific implementation mode of the impedance difference compensation circuit 701, reference can be made to the embodiments of FIGS. 1-7, it is not repeatedly described herein. As described above, since the impedance difference compensation circuit 701 may compensate the impedance differences of the drive signals in the signal transmission paths, so that the multiple drive signals may keep consistent transmission rate and consistent transmission time in the display panel driving circuit, the display panel may receive multiple drive signals at the same time to acquire large amount of image data, the display panel may display uniform and dynamic images in real time, so that a problem that the image is uneven due to the fact that the drive signals are inconsistent in the signal transmission process is solved, the real viewing experience effect of the user is enhanced; therefore, the impedance difference compensation system 70 in the embodiment of the present disclosure effectively solves the problem that the display panel may not display coordinate images and thus may not be widely applied in different industrial fields due to impedance difference existing in different signal transmission paths in the transmission process of the drive signals in the exemplary technology.

In conclusion, the impedance difference compensation circuit in the embodiments of the present disclosure may greatly improve the quality and the definition of images in the display panel, and bring a good and real viewing experience to the user, may be widely applied in various industrial fields, and has extremely high industrial application value.

The aforementioned embodiments are only optional embodiments of the present disclosure, and are not intended to limit the present disclosure. For the person of ordinary skill in the art, the present disclosure may have various modifications and changes. Any modification, equivalent replacement, improvement, and so on, which are made within the spirit and the principle of the present disclosure, should all be included in the protection scope of the claims of the present disclosure.

1. An impedance difference compensation circuit, which is applied in a display panel driving circuit, wherein the display panel driving circuit comprises:
a drive integrated circuit, including multiple signal transmission channels respectively configured to access drive signals and being arranged at intervals;
a first signal processing circuit electrically connected with the multiple signal transmission channels respectively and configured to respectively transmit multiple drive signals;
a second signal processing circuit electrically connected with the first signal processing circuit and configured to perform integrated conversion on the multiple drive signals; and
a signal transmission circuit electrically connected with the second signal processing circuit, wherein the signal transmission circuit comprises multiple display wirings which are configured to output the drive signals and are arranged in array, and the signal transmission channels are arranged corresponding to the display wirings respectively;
wherein the impedance difference compensation circuit comprises a resistance device, the resistance device is connected in series or in parallel to an input of the first signal processing circuit, and is arranged such that the equivalent resistances between the multiple signal transmission channels and the respective display wirings are identical; and
wherein the resistance device comprises at least one resistor.

2. The impedance difference compensation circuit according to claim 1, wherein
the impedance difference compensation circuit is configured to be arranged in the drive integrated circuit, or alternatively,
the impedance difference compensation circuit is configured to be arranged on a wiring between the drive integration circuit and the first signal processing circuit.

3. The impedance difference compensation circuit according to claim 1, wherein the resistance device comprises two resistors connected in parallel, and the two resistors connected in parallel are a first resistor and a second resistor respectively;
wherein a first end of the first resistor and a first end of the second resistor are in common connection with the signal transmission channel, a second end of the first resistor and a second end of the second resistor are in common connection with the first signal processing circuit, and a resistance value of the first resistor and a resistance value of the second resistor meet the following condition:
$$\frac{1}{{R}_{1}} + \frac{1}{{R}_{2}} = \frac{1}{{R}_{0}}$$
In aforesaid formula, R₁ represents the resistance value of the first resistor, R₂ represents the resistance value of the second resistor, R₀ represents preset equivalent parameter.

4. The impedance difference compensation circuit according to claim 1, wherein the resistance device comprises three resistors connected in parallel, and the three resistors connected in parallel are a third resistor, a fourth resistor and a fifth resistor respectively;
wherein a first end of the third resistor, a first end of the fourth resistor and a first end of the fifth resistor are in common connection with the signal transmission channel, a second end of the third resistor, a second end of the fourth resistor and a second end of the fifth resistor are in common connection with the first signal processing circuit, and a resistance value of the third resistor, a resistance value of the fourth resistor and a resistance value of the fifth resistor meet the following condition:
$$\frac{1}{{R}_{3}} + \frac{1}{{R}_{4}} + \frac{1}{{R}_{5}} = \frac{1}{{R}_{0}}$$
In aforesaid formula, R₃ represents the resistance value of the third resistor, R₄ represents the resistance value of the fourth resistor, R₅ represents the resistance value of the fifth resistor, R₀ represents preset equivalent parameter.

5. The impedance difference compensation circuit according to claim 1, wherein the resistance device comprises two resistors connected in series, and the two resistors connected in series are a sixth resistor and a seventh resistor respectively;
wherein a first end of the sixth resistor is connected with the signal transmission channel, a second end of the sixth resistor is connected with a first end of the seventh resistor, a second end of the seventh resistor is connected with the first signal processing circuit, and a resistance value of the sixth resistor and a resistance value of the seventh resistor meet the following condition:
R₆+R₇=R₀
In aforesaid formula, R₆ represents the resistance value of the sixth resistor, R₇ represents the resistance value of the seventh resistor, R₀ represents preset equivalent parameter.

6. The impedance difference compensation circuit according to claim 1, wherein the resistance device comprises three resistors connected in series, and the three resistors connected in series are an eighth resistor, a ninth resistor and a tenth resistor respectively;
wherein a first end of the eighth resistor is connected with the signal transmission channel, a second end of the eighth resistor is connected with a first end of the ninth resistor, a second end of the ninth resistor is connected with a first end of the tenth resistor, a second end of the tenth resistor is connected with the first signal processing circuit, and a resistance value of the eighth resistor, a resistance value of the ninth resistor and a resistance value of the tenth resistor meet the following condition:
R₈+R₉+R₁₀=R₀
In aforesaid formula, R₈ represents the resistance value of the eighth resistor, R₉ represents the resistance value of the ninth resistor, R₁₀ represents the resistance value of the tenth resistor, R₀ represents preset equivalent parameter.

7. The impedance difference compensation circuit according to claim 1, wherein the signal transmission channel comprises:
a buffer configured to buffer the drive signals.

8. The impedance difference compensation circuit according to claim 1,
wherein the number of the signal transmission channels is equal to the number of the display wirings.

9. The impedance difference compensation circuit according to claim 1, wherein the multiple signal transmission channels are arranged to be distributed at equal intervals in the drive integrated circuit; and
the multiple display wirings are arranged to be distributed at equal intervals in the signal transmission circuit.

10. A display panel, comprising:
a drive integrated circuit which comprises multiple signal transmission channels respectively configured to access drive signals and being arranged at intervals;
a first signal processing circuit electrically connected with the multiple signal transmission channels respectively and configured to transmit the multiple drive signals respectively;
a second signal processing circuit electrically connected with the first signal processing circuit and configured to perform integrated conversion on the multiple drive signals; and
a signal transmission circuit electrically connected with the second signal processing circuit, wherein the signal transmission circuit comprises multiple display wirings which are configured to output the drive signals and are arranged in array, and wherein the multiple signal transmission channels are arranged corresponding to the multiple display wirings respectively;
a video display circuit electrically connected with the signal transmission circuit and configured to perform video display according to the multiple drive signals; and
a resistance device connected in series or in parallel with an input of the first signal processing circuit and configured to enable equivalent resistances between the multiple signal transmission channels and the multiple display wirings be identical; wherein the resistance device comprises at least one resistor.

11. The display panel according to claim 10, wherein the impedance difference compensation circuit is configured to be arranged in the drive integrated circuit, or alternatively, the impedance difference compensation circuit is configured to be arranged on a wiring between the drive integration circuit and the first signal processing circuit.

12. The display panel according to claim 10, wherein the resistance device comprises two resistors connected in parallel, and the two resistors connected in parallel are an eleventh resistor and a twelfth resistor respectively;
wherein a first end of the eleventh resistor and a first end of the twelfth resistor are in common connection with the signal transmission channel, a second end of the eleventh resistor and a second end of the twelfth resistor are in common connection with the first signal processing circuit, and a resistance value of the eleventh resistor and a resistance value of the twelfth resistor meet the following condition:
$$\frac{1}{{R}_{11}} + \frac{1}{{R}_{12}} = \frac{1}{{R}_{0}}$$
In aforesaid formula, R₁₁ represents the resistance value of the first resistor, R₁₂ represents the resistance value of the second resistor, R₀ represents preset equivalent parameter.

13. The display panel according to claim 10, wherein the resistance device comprises three resistors connected in parallel, and the three resistors connected in parallel are a thirteenth resistor, a fourteenth resistor and a fifteenth resistor respectively;
wherein a first end of the thirteenth resistor, a first end of the fourteenth resistor and a first end of the fifteenth resistor are in common connection with the signal transmission channel, a second end of the thirteenth resistor, a second end of the fourteenth resistor and a second end of the fifteenth resistor are in common connection with the first signal processing circuit, and a resistance value of the thirteenth resistor, a resistance value of the fourteenth resistor and a resistance value of the fifteenth resistor meet the following condition:
$$\frac{1}{{R}_{13}} + \frac{1}{{R}_{14}} + \frac{1}{{R}_{15}} = \frac{1}{{R}_{0}}$$
In aforesaid formula, R₁₃ represents the resistance value of the third resistor, R₁₄ represents the resistance value of the fourth resistor, R₁₅ represents the resistance value of the fifth resistor, R₀ represents preset equivalent parameter.

14. The impedance difference compensation circuit according to claim 10, wherein the resistance device comprises two resistors connected in series, and the two resistors connected in series are a sixteenth resistor and a seventeenth resistor respectively;
wherein a first end of the sixteenth resistor is connected with the signal transmission channel, a second end of the sixteenth resistor is connected with a first end of the seventeenth resistor, a second end of the seventeenth resistor is connected with the first signal processing circuit, and a resistance value of the sixteenth resistor and a resistance value of the seventeenth resistor meet the following condition:
R₁₆+R₁₇=R₀
In aforesaid formula, R₁₆ represents the resistance value of the sixth resistor, R₁₇ represents the resistance value of the seventh resistor, R₀ represents preset equivalent parameter.

15. The display panel according to claim 10, wherein the resistance device comprises three resistors connected in series, and the three resistors connected in series are an eighteenth resistor, a nineteenth resistor and a twentieth resistor respectively;
wherein a first end of the eighteenth resistor is connected with the signal transmission channel, a second end of the eighteenth resistor is connected with a first end of the nineteenth resistor, a second end of the nineteenth resistor is connected with a first end of the twentieth resistor, a second end of the twentieth resistor is connected with the first signal processing circuit, and a resistance value of the eighteenth resistor, a resistance value of the nineteenth resistor and a resistance value of the twentieth resistor meet the following condition:
R₁₈+R₁₉+R₂₀=R₀
In aforesaid formula, R₁₈ represents the resistance value of the eighth resistor, R₁₉ represents the resistance value of the ninth resistor, R₂₀ represents the resistance value of the tenth resistor, R₀ represents preset equivalent parameter.

16. The display panel according to claim 10, wherein the signal transmission channel comprises:
a buffer configured to buffer the drive signals.

17. The display panel according to claim 10, wherein the number of the signal transmission channels is equal to the number of the display wirings.

18. The display panel according to claim 10, wherein the multiple signal transmission channels are arranged to be distributed at equal intervals in the drive integrated circuit; and
the multiple display wirings are arranged to be distributed at equal intervals in the signal transmission circuit.

19. A mobile terminal, comprising:
a signal collector configured to generate multiple drive signals according to image information; and
a display panel collected with the signal collector and configured to perform video display according to the multiple drive signals;
wherein the display panel comprises:
a drive integrated circuit, including multiple signal transmission channels respectively configured to receive drive signals and being arranged at intervals;
a first signal processing circuit electrically connected with the multiple signal transmission channels respectively and configured to transmit the multiple drive signals respectively;
a second signal processing circuit electrically connected with the first signal processing circuit and configured to perform integrated conversion on the multiple drive signals; and
a signal transmission circuit electrically connected with the second signal processing circuit, wherein the signal transmission circuit comprises multiple display wirings which are configured to output the drive signals and are arranged in array, wherein the multiple signal transmission channels are arranged corresponding to the multiple display wirings respectively;
a video display circuit electrically connected with the signal transmission circuit and configured to perform video display according to the multiple drive signals; and
a resistance device connected in series or in parallel with an input of the first signal processing circuit and configured to enable equivalent resistances between the multiple signal transmission channels and the multiple display wirings be identical; wherein the resistance device comprises at least one resistor.

20. The mobile terminal according to claim 19, wherein the mobile terminal is a mobile phone or a tablet computer.
